(19) United States
(12) Patent Application Publication
(10) Pub. No.: US 2025/0313952 A1
(43) Pub. Date: Oct. 9, 2025

(54) CHEMICAL SOURCE VESSEL AND REACTION SYSTEM

(71) Applicant: ASM IP Holding B.V., Almere (NL)

(72) Inventor: Andrew Michael Yednak, III, Phoenix, AZ (US)

(21) Appl. No.: 19/097,971

(22) Filed: Apr. 2, 2025

Related U.S. Application Data
(60) Provisional application No. 63/575,183, filed on Apr. 5, 2024.

(51) Int. Cl. C23C 16/455; C23C 16/52

(52) U.S. Cl. CPC C23C 16/45544; C23C 16/52

(57) ABSTRACT

A chemical vessel used for holding a liquid chemical precursor is disclosed comprising a liquid level sensor tube. The liquid level sensor tube is configured to operate in an environment where the liquid chemical precursor is heated to a point of boiling or vaporization. The liquid level sensor tube comprises housing with a slot built in to prevent any false readings of sensors disposed within the liquid level sensor tube. The liquid level sensor tube can be protected by a shield from unwanted liquid splashing during introduction of liquid into the environment. The liquid may be introduced through an inlet, and a splash wall may be between the liquid level sensor tube and the inlet port, thereby reducing the risk of unwanted liquid being displaced on the liquid level sensor tube.

### CROSS-REFERENCE TO RELATED APPLICATIONS

This application is a nonprovisional of, and claims priority to and the benefit of, U.S. Provisional Patent Application No. 63/575,183, filed Apr. 5, 2024 and entitled “CHEMICAL SOURCE VESSEL AND REACTION SYSTEM,” which is hereby incorporated by reference herein.

### FIELD OF INVENTION

The present disclosure generally relates to an apparatus for processing semiconductor wafers. More particularly, the disclosure relates to a liquid level sensor for a vessel in the apparatus for providing a vaporized gas precursor from a liquid source used in a system for depositing a film on a semiconductor wafer in an atomic layer deposition (ALD) process, a chemical vapor deposition (CVD) process, or an epitaxial deposition process, for example. The liquid level sensor would be for use in a high temperature environment or an environment where a liquid is boiled or vaporized into a gas.

### BACKGROUND OF THE DISCLOSURE

In film deposition systems, gases are passed over semiconductor wafers, whereby the gases may react with other gaseous precursors in order to form a particular film. The gases may be produced by boiling or vaporizing a liquid in a vessel.

It may be important to know an amount of precursor in the vessel in order to monitor an amount of vapor produced as well as an amount of liquid left. The monitoring may be accomplished from the use of a liquid level sensor, such as the one described in U.S. Pat. No. 10,151,618 to Birtcher et al., entitled “Ultrasonic Liquid Level Sensing Systems.” With an appropriate monitoring of the vessel, a refill of the vessel may take place as needed.

However, the process of boiling or vaporizing the liquid in the vessel may cause bubbles to rise in prior art liquid level sensor tubes, leading to a false reading of the prior art liquid level sensors. The false readings may be due to random wet and dry signals, leading to triggering safety measures in the chemical vessel and the system for depositing the semiconductor film.

As a result, an accurate liquid level sensor for use in a high temperature environment or a boiling environment within a chemical source vessel is desired.

### SUMMARY OF THE DISCLOSURE

A chemical vessel for providing a chemical precursor for use in deposition of semiconductor films onto a substrate is disclosed. The chemical vessel comprises: a vessel housing; and a liquid level sensor tube extending from a top of the vessel housing, the liquid level sensor tube comprising: a liquid level sensor tube housing; a slot built into the liquid level sensor tube housing; and a plurality of sensors disposed within the liquid level sensor tube housing, the plurality of sensors configured to indicate a level of a liquid chemical precursor within the vessel housing. In accordance with examples of the disclosure, the chemical vessel further comprises a shield coupled to the top of the vessel housing and surrounding at least a portion of the liquid level sensor tube housing, and/or a splash wall extending vertically from the top of the vessel housing in between the liquid level sensor tube housing and an inlet port.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a perspective illustration of a chemical vessel in accordance with at least one embodiment of the invention.

FIG. 2 is a cross-sectional illustration of a chemical vessel in accordance with at least one embodiment of the invention.

FIG. 3A is a perspective illustration of a liquid level sensor in accordance with at least one embodiment of the invention.

FIG. 3B is a cross-sectional illustration of a liquid level sensor in accordance with at least one embodiment of the invention.

FIG. 4A is a perspective illustration of a liquid level sensor in accordance with at least one embodiment of the invention.

FIG. 4B is a cross-sectional illustration of a liquid level sensor in accordance with at least one embodiment of the invention.

FIG. 5A is a perspective illustration of a liquid level sensor in accordance with at least one embodiment of the invention.

FIG. 5B is a cross-sectional illustration of a liquid level sensor in accordance with at least one embodiment of the invention.

FIG. 6 is a schematic illustration of a reaction system in accordance with at least one embodiment of the invention.

FIG. 7 is a perspective illustration of a chemical vessel in accordance with at least one embodiment of the invention.

FIG. 8 is a perspective illustration of a chemical vessel in accordance with at least one embodiment of the invention.

FIG. 9 is a perspective illustration of a chemical vessel in accordance with at least one embodiment of the invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which may react and/or decompose on a substrate surface to produce a desired deposition.

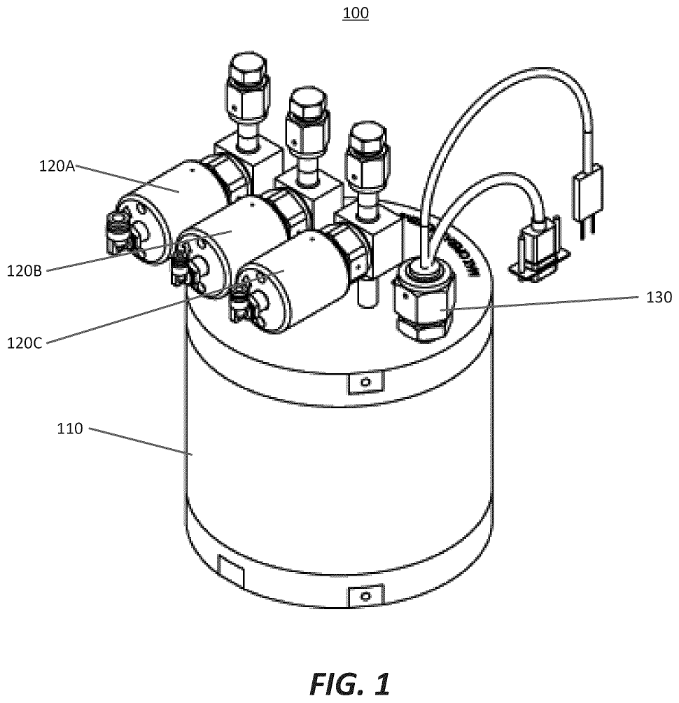

Chemical vessels may be used to hold a liquid precursor that is later vaporized when used to form a semiconductor film. FIG. 1 illustrates a chemical vessel 100 in accordance with at least one embodiment of the invention. The chemical vessel 100 comprises a vessel housing 110, a first valve 120A, a second valve 120B, a third valve 120C, and a liquid level sensor port 130.

The first valve 120A may be connected to a gas source (not illustrated). The second valve 120B may be connected to a vacuum source or a liquid source (not illustrated). The third valve 120C may be connected to a reaction chamber (not illustrated), where deposition of a film may take place. The valves 120A-120C may comprise a manual or pneumatic valve. The liquid level sensor port 130 may allow for electrical connections to a controller, to a processor, to a thermocouple, or to a heating element (not illustrated). These electrical connections may be located elsewhere on the chemical vessel 100.

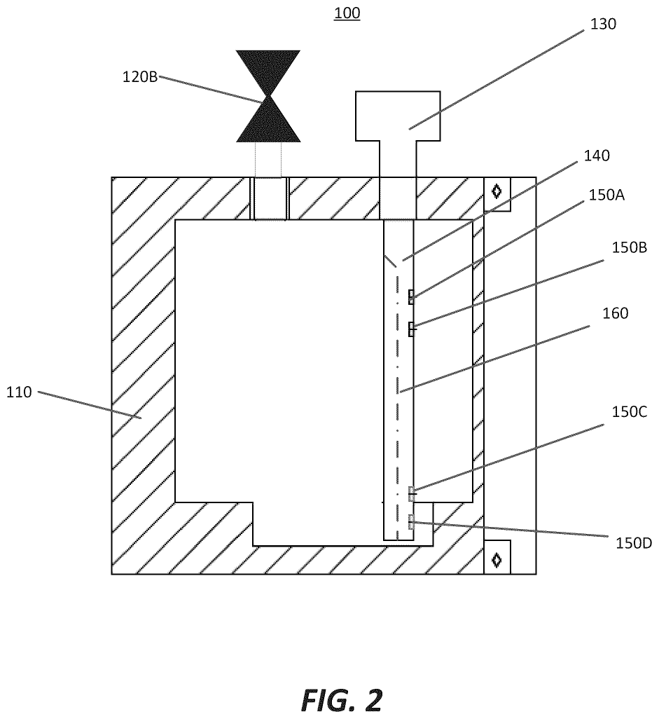

The chemical vessel 100 may include additional parts illustrated in FIG. 2. The chemical vessel 100 may also include a level sensor tube 140, and a plurality of sensors 150A-150D. The level sensor tube 140 may be connected to the level sensor tube port 130.

The plurality of sensors 150A-150D may be located at particular spots along the level sensor tube 140 to indicate that a liquid inside the vessel housing 110 is at a particular level. For example, a reading at sensor 150A may indicate that the liquid inside the vessel housing 110 is at a 75% level, a reading at sensor 150B may indicate that the liquid inside the vessel housing 110 is at a 65% level, a reading at sensor 150C may indicate that the liquid inside the vessel housing 110 is at a 5% level, and a reading at sensor 150D may indicate that the liquid inside the vessel housing 110 is at a 1% level. The sensors 150A-150D may be located at other levels to show the level of liquid inside the vessel housing 110 to be at other numerical levels. The level sensor tube 140 may have a slot 160 that allows for accurate measurement of the liquid when the liquid inside the vessel housing 110 is boiling.

Prior approaches have used a liquid level sensor tube that is circular in shape without a slot, in a shape that resembles a drinking straw. The prior approach liquid level sensor tube would have a fluid chamber in the middle. The liquid level sensor tube in accordance with at least one embodiment of the invention may be made in different shapes, but the existence of the slot 160 will allow for an accurate measurement of the level without any false readings.

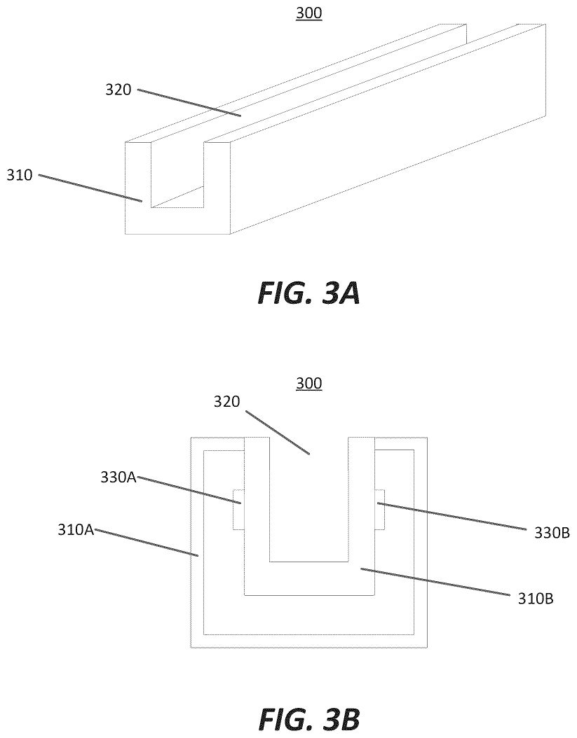

FIG. 3A illustrates a liquid level sensor tube 300 in accordance with at least one embodiment of the invention. The liquid level sensor tube 300 comprises a U-shaped housing 310 with a slot/channel 320 built in to the liquid level sensor tube 300. The U-shaped housing 310 may comprise metals (such as stainless steel), plastics (such as Teflon), ceramics, or any combination thereof, as long as the materials have the ability to withstand a boiling environment of potentially caustic chemicals.

The slot/channel 320 is shown to be rectangular in shape. The slot/channel 320 may be continuously open throughout or may be closed at regular intervals along the liquid level sensor tube 300. The existence of the slot/channel 320 allows for a diffusion of surface tension in bubbles formed when the liquid in the chemical vessel is boiled or vaporized. By lessening the surface tension in the bubbles formed, this would prevent any false readings of the sensors in the liquid level sensor tube 300. In addition, the channel/slot 320 that is completely open would allow for pressures measured inside the slot/channel 320 to be equal to that of the liquid surrounding the liquid level sensor tube 300 or generally within the chemical vessel 100.

Prior art approaches for the liquid level sensor tube may use a completely closed tube with a few vent holes; this would result in a difference between a pressure inside the liquid level sensor tube and a pressure outside the tube in the vessel, leading to a higher level reading by the liquid level sensor. The design in accordance with at least one embodiment of the invention would equalize the pressures inside and outside the liquid level sensor tube, resulting in less false level readings during fast pulsing operations.

FIG. 3B illustrates a cross-section of the liquid level sensor tube 300 at a location where a sensor is placed. The U-shaped housing 310 of the liquid level sensor tube 300 comprises two parts: an outer housing portion 310A and an inner housing portion 310B. The liquid level sensor tube 300 also comprises a first sensor 330A and a second sensor 330B. The first sensor 330A and the second sensor 330B may comprise: ultrasonic sensors; piezoelectric sensors; capacitance sensors; conductance sensors; or optoelectronic sensors. It may be possible that the first sensor 330A may be a signal transmitter, while the second sensor 330B may be a signal receiver. It may also be possible that the first sensor 330A may be both a signal transmitter and a signal receiver, while the second sensor 330B may be a signal reflector. Furthermore, it may be also possible that first sensor 330A and the second sensor 330B may be both signal transmitters and signal receivers.

The outer housing portion 310A is sealed to the inner housing portion 310B with caps located at the top and bottom of the liquid level sensor tube 300 in order to provide a sealed and dry environment within the U-shaped housing 310. The sealed and dry environment will allow for the first sensor 330A and the second sensor 330B to be protected from the liquid in the chemical vessel.

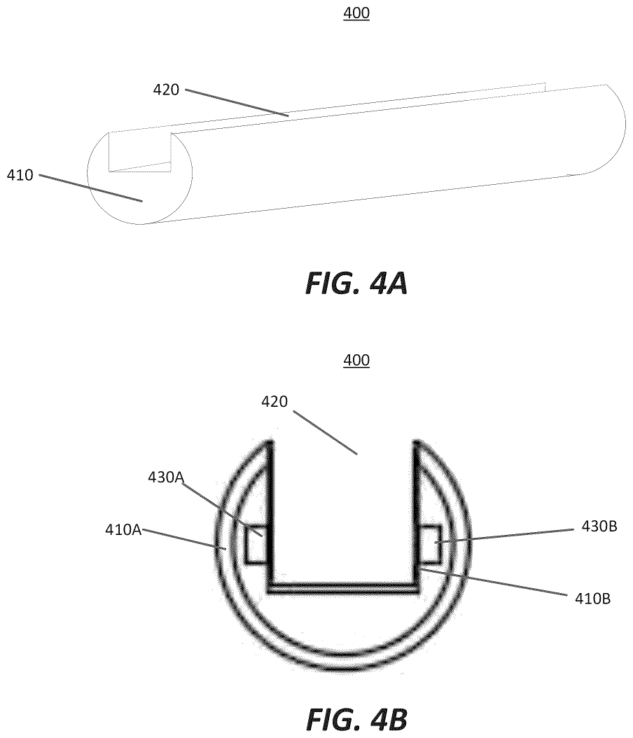

FIG. 4A illustrates a liquid level sensor tube 400 in accordance with at least one embodiment of the invention. The liquid level sensor tube 400 comprises a circular housing 410 with a slot/channel 420 built in to the liquid level sensor tube 400. The circular housing 410 may comprise metals (such as stainless steel), plastics (such as Teflon), ceramics, or any combination thereof, as long as the materials have the ability to withstand a boiling environment of potentially caustic chemicals.

The slot/channel is shown to be rectangular in shape. The existence of the slot/channel 420 allows for a diffusion of surface tension in bubbles formed when the liquid in the chemical vessel is boiled or vaporized. By lessening the surface tension in the bubbles formed, this would prevent any false readings of the sensors in the liquid level sensor tube 400. In addition, the channel/slot 420 that is completely open would allow for pressures measured inside the slot/channel 420 to be equal to that of the liquid surrounding the liquid level sensor tube 400 or generally within the chemical vessel 100.

Prior art approaches for the liquid level sensor tube may use a completely closed tube with a few vent holes; this would result in a difference between a pressure inside the liquid level sensor tube and a pressure outside the tube in the vessel, leading to a higher level reading by the liquid level sensor. The design in accordance with at least one embodiment of the invention would equalize the pressures inside and outside the liquid level sensor tube, resulting in less false level readings during fast pulsing operations.

FIG. 4B illustrates a cross-section of the liquid level sensor tube 400 at a location where a sensor is placed. The circular housing 410 of the liquid level sensor tube 400 comprises two parts: an outer housing portion 410A and an inner housing portion 410B. The liquid level sensor tube 400 also comprises a first sensor 430A and a second sensor 430B. The first sensor 430A and the second sensor 430B may comprise: ultrasonic sensors, such as those manufactured by ultrasonic sensors; piezoelectric sensors; capacitance sensors; conductance sensors; or optoelectronic sensors. It may be possible that the first sensor 430A may be a signal transmitter, while the second sensor 430B may be a signal receiver. It may also be possible that the first sensor 430A may be both a signal transmitter and a signal receiver, while the second sensor 430B may be a signal reflector. Furthermore, it may be also possible that first sensor 430A and the second sensor 430B may be both signal transmitters and signal receivers.

The outer housing portion 410A is sealed to the inner housing portion 410B with caps located at the top and bottom of the liquid level sensor tube 400 in order to provide a sealed and dry environment within the circular housing 410. The sealed and dry environment will allow for the first sensor 430A and the second sensor 430B to be protected from the liquid in the chemical vessel.

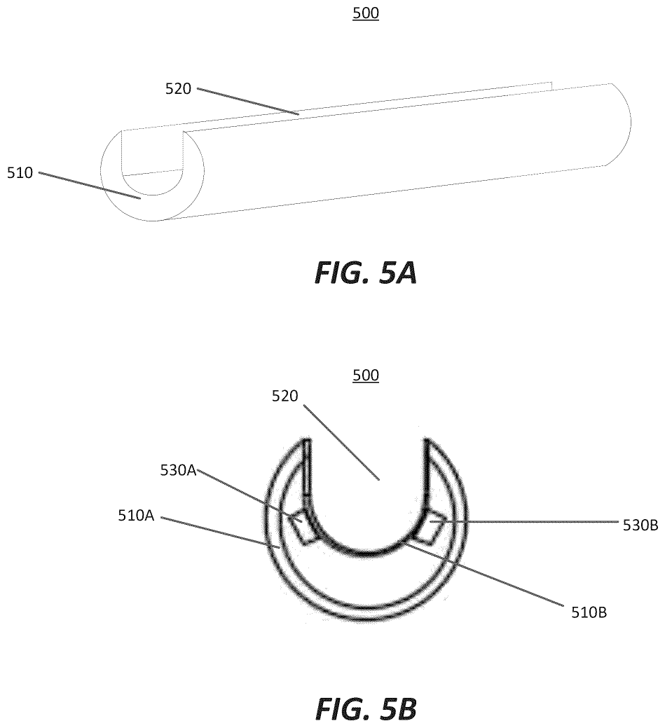

FIG. 5A illustrates a liquid level sensor tube 500 in accordance with at least one embodiment of the invention. The liquid level sensor tube 500 comprises a circular housing 510 with a rounded slot 520 built in to the liquid level sensor tube 500. The circular housing 510 may comprise metals (such as stainless steel), plastics (such as Teflon), ceramics, or any combination thereof, as long as the materials have the ability to withstand a boiling environment of potentially caustic chemicals.

The rounded slot/channel 520 is shown have at least one rounded surface. The existence of the rounded slot 520 allows for a diffusion of surface tension in bubbles formed when the liquid in the chemical vessel is boiled or vaporized. By lessening the surface tension in the bubbles formed, this would prevent any false readings of the sensors in the liquid level sensor tube 500. In addition, the channel/slot 520 that is completely open would allow for pressures measured inside the slot/channel 520 to be equal to that of the liquid surrounding the liquid level sensor tube 500 or generally within the chemical vessel 100.

Prior art approaches for the liquid level sensor tube may use a completely closed tube with a few vent holes; this would result in a difference between a pressure inside the liquid level sensor tube and a pressure outside the tube in the vessel, leading to a higher level reading by the liquid level sensor. The design in accordance with at least one embodiment of the invention would equalize the pressures inside and outside the liquid level sensor tube, resulting in less false level readings during fast pulsing operations.

FIG. 5B illustrates a cross-section of the liquid level sensor tube 500 at a location where a sensor is placed. The circular housing 510 of the liquid level sensor tube 500 comprises two parts: an outer housing portion 510A and an inner housing portion 510B. The liquid level sensor tube 500 also comprises a first sensor 530A and a second sensor 530B. The first sensor 530A and the second sensor 530B may comprise: ultrasonic sensors; piezoelectric sensors; capacitance sensors; conductance sensors; or optoelectronic sensors. It may be possible that the first sensor 530A may be a signal transmitter, while the second sensor 530B may be a signal receiver. It may also be possible that the first sensor 530A may be both a signal transmitter and a signal receiver, while the second sensor 530B may be a signal reflector. Furthermore, it may be also possible that first sensor 530A and the second sensor 530B may be both signal transmitters and signal receivers.

The outer housing portion 510A is sealed to the inner housing portion 510B with caps located at the top and bottom of the liquid level sensor tube 500 in order to provide a sealed and dry environment within the circular housing 510. The sealed and dry environment will allow for the first sensor 530A and the second sensor 530B to be protected from the liquid in the chemical vessel.

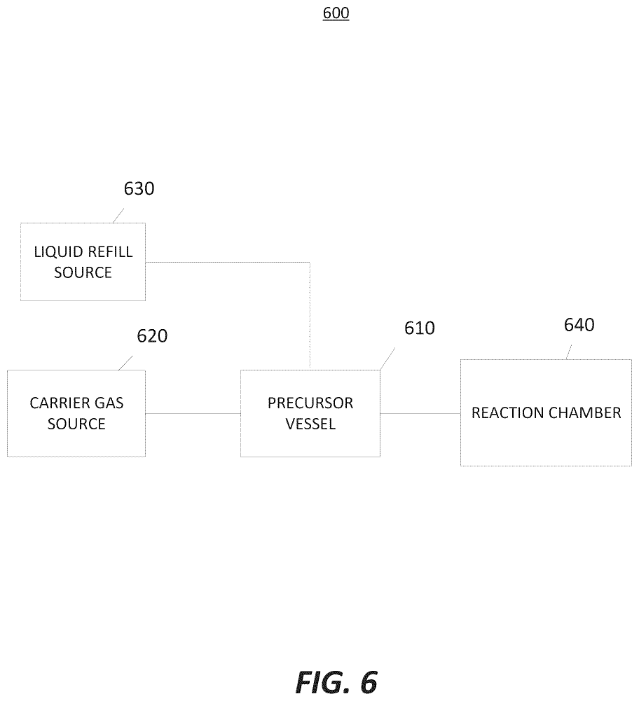

FIG. 6 illustrates a reaction system 600 in accordance with at least one embodiment of the invention. The reaction system 600 may comprise: a precursor vessel 610; a carrier gas source 620; a liquid refill source 630; and a reaction chamber 640. The precursor vessel 610 comprises a vessel and a liquid level sensor as previously described. The carrier gas source 620 (which can be optional) may provide a carrier gas (such as nitrogen or other inert gas, for example) to the precursor vessel 610 that will carry a vaporized precursor out of the precursor vessel 610 and into the reaction chamber 640, where it may react on a semiconductor wafer disposed within the reaction chamber 640. The liquid refill source 630 may be configured to provide additional liquid precursor to the precursor vessel 610 should a liquid level sensor determine that the level of liquid precursor within the precursor vessel 610 is too low.

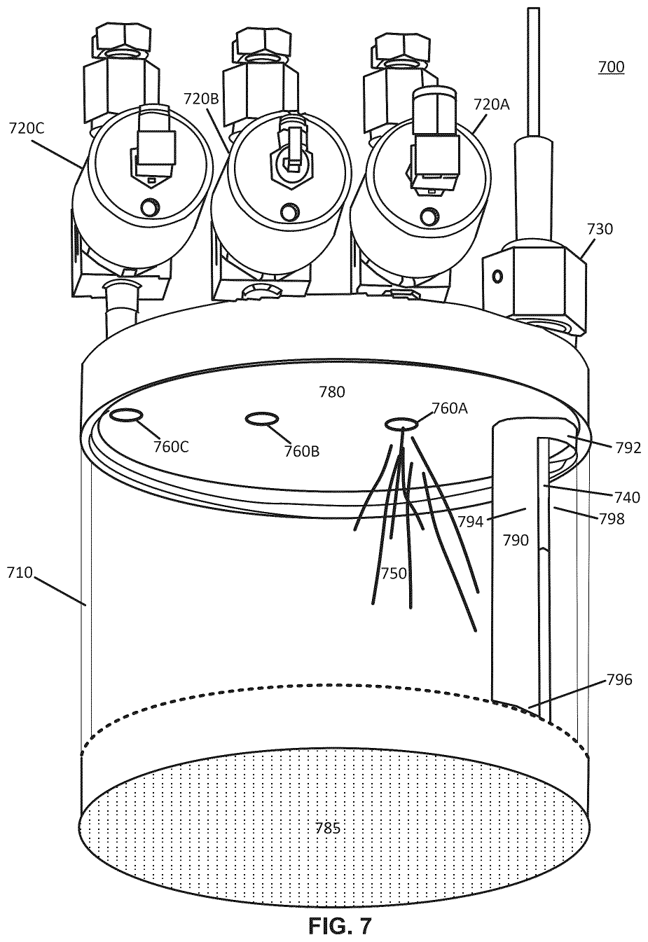

FIG. 7 illustrates a chemical vessel 700 in accordance with at least one embodiment of the disclosure. The chemical vessel 700 can be used as precursor vessel 610 within reaction system 600. The chemical vessel 700 comprises a vessel housing 710, a first valve 720A, a second valve 720B, a third valve 720C, and a liquid level sensor port 730.

The first valve 720A may be connected to a vacuum source or a liquid source (not illustrated). The second valve 720B may be connected to a gas source (not illustrated). The third valve 720C may be connected to a reaction chamber (not illustrated), where deposition of a film may take place. The valves 720A-720C may comprise a manual or pneumatic valve. The liquid level sensor port 730 may allow for electrical connections to a controller, to a processor, to a thermocouple, or to a heating element (not illustrated). These electrical connections may be located elsewhere on the chemical vessel 700.

The chemical vessel 700 may include additional parts similar to those illustrated in FIGS. 2-5B. The chemical vessel 700 may also include a liquid level sensor tube 740 (such as level sensor tubes 140 and other embodiments of level sensor tubes described herein), and a plurality of sensors (such as sensors 150A-150D). The liquid level sensor tube 740 may be connected to the liquid level sensor port 730. The vessel housing 710 comprises a top of the vessel housing 780, wherein the top of the vessel housing comprises valve inlet ports 760A-760C, which are in fluid communication with valves 720A-720C. The vessel housing 710 also comprises a bottom of the vessel housing 785.

When liquid precursor is deposited within the vessel housing 710, a portion of a liquid precursor 750 can splash on the liquid level sensor tube 740, causing a false reading of the liquid level within the vessel housing 710. Therefore, it is desirable to protect the liquid level sensor tube 740 from receiving any inadvertent liquid precursor 750. A shield 790 can be coupled to the top of the vessel housing 780, to surround and protect a portion of the liquid level sensor tube 740 from any splashing from liquid precursor 750. The shield 790 can be welded to the top of the vessel housing 780. In additional embodiments, the shield 790 can be welded to the bottom of the vessel housing with a space remaining between the shield 790 and the top of the vessel housing 280. The space can be between about 0.5 millimeters and about 3 millimeters, or between about 1 millimeter and about 2 millimeters.

The shield 790 comprises a top portion 792, which circumferentially surrounds the liquid level sensor tube 740; and a bottom portion 796, which partially surrounds the liquid level sensor tube 740. The shield 790 comprises a cover wall 794, which is an area of the shield extending vertically from the top portion 792 to a bottom portion 796. The shield 790 comprises an opening 798, which is a gap from the top portion 792 to the bottom portion 796. The shield 790 can extend from the top of the vessel housing 780 to between about 5 millimeters and about 1 millimeter from the bottom of the vessel housing 785, or between about 2 millimeters and about 1 millimeter from the bottom of the vessel housing 785.

The liquid level sensor tube 740, in accordance with at least one embodiment of the invention may comprise a slot (such as slot 160), which allows for a measurement of the liquid level in the vessel housing 710. The cover wall 794 is disposed in front of the slot to prevent liquid from inadvertently entering the slot. A circumference of the top portion 792 is configured to be between about 1 millimeter and about 12 millimeters more than a circumference of the liquid level sensor tube 740, between about 2 millimeters and about 10 millimeters more than a circumference of the liquid level sensor tube 740, or between about 3 millimeters and about 9 millimeters more than a circumference of the liquid level sensor tube 740.

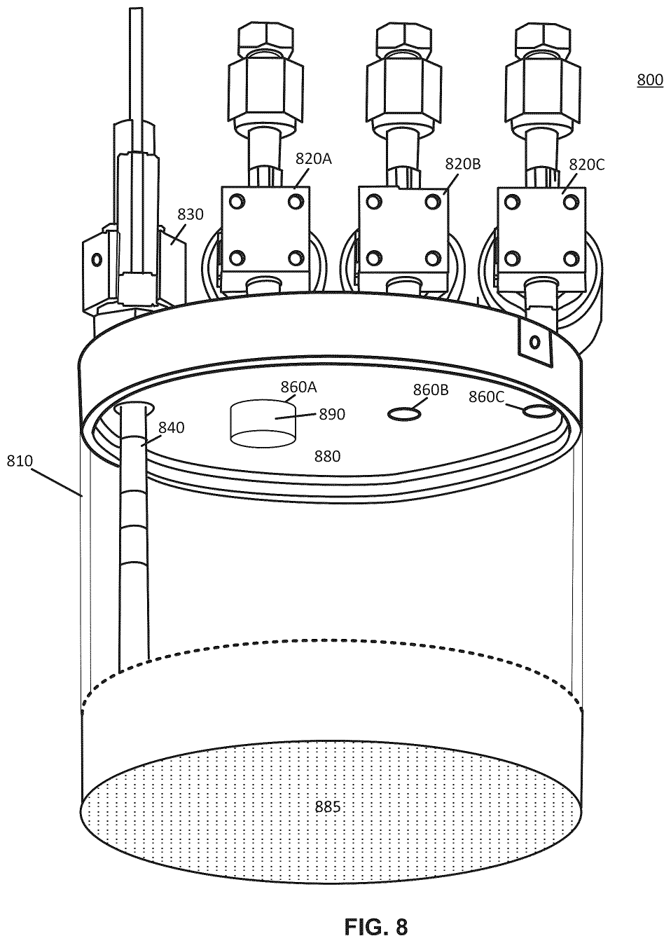

FIG. 8 illustrates a chemical vessel 800 in accordance with at least one embodiment of the invention. The chemical vessel 800 can be used as precursor vessel 610 within reaction system 600. The chemical vessel 800 comprises a vessel housing 810, a first valve 820A, a second valve 820B, a third valve 820C, and a liquid level sensor port 830.

The first valve 820A may be connected to a vacuum source or a liquid source (not illustrated). The second valve 820B may be connected to a reaction chamber (not illustrated), where deposition of a film may take place. The third valve 820C may be connected to a gas source (not illustrated). The valves 820A-820C may comprise a manual or pneumatic valve. The liquid level sensor port 830 may allow for electrical connections to a controller, to a processor, to a thermocouple, or to a heating element (not illustrated). These electrical connections may be located elsewhere on the chemical vessel 800.

The chemical vessel 800 may include additional parts similar to those illustrated in FIGS. 2-5B. The chemical vessel 800 may also include a liquid level sensor tube 840 (such as level sensor tubes 140 and other embodiments of level sensor tubes described herein), and a plurality of sensors (such as sensors 150A-150D). The liquid level sensor tube 840 may be connected to the liquid level sensor port 830. The vessel housing 810 comprises a top of the vessel housing 880, wherein the top of the vessel housing comprises valve inlet ports 860A-860C, which are in fluid communication with valves 820A-820C. The vessel housing 810 also comprises a bottom of the vessel housing 885.

A splash wall 890 is coupled to, and extends vertically from, the top of the vessel housing 880. A top surface of the splash wall (not illustrated) is (e.g., fixedly) coupled to the top of the vessel housing 880 at valve inlet port 860A. The splash wall 890 is configured to be between the liquid level sensor tube 840 and the inlet port 860A. Therefore, the splash wall 890 is fluidly coupled to the valve inlet port 860A and is configured to prevent introduction of precursor to the chemical vessel 800 from contacting a top of the liquid level sensor 840. In certain embodiments, the top surface of the splash wall can be welded to the top of the vessel housing 880. The splash wall 890 comprises a splash wall bottom surface (not illustrated), which extends from between about 10 millimeters and about 20 millimeters from the top of the vessel housing 880, or between about 10 millimeters and about 15 millimeters from the top of the vessel housing 880.

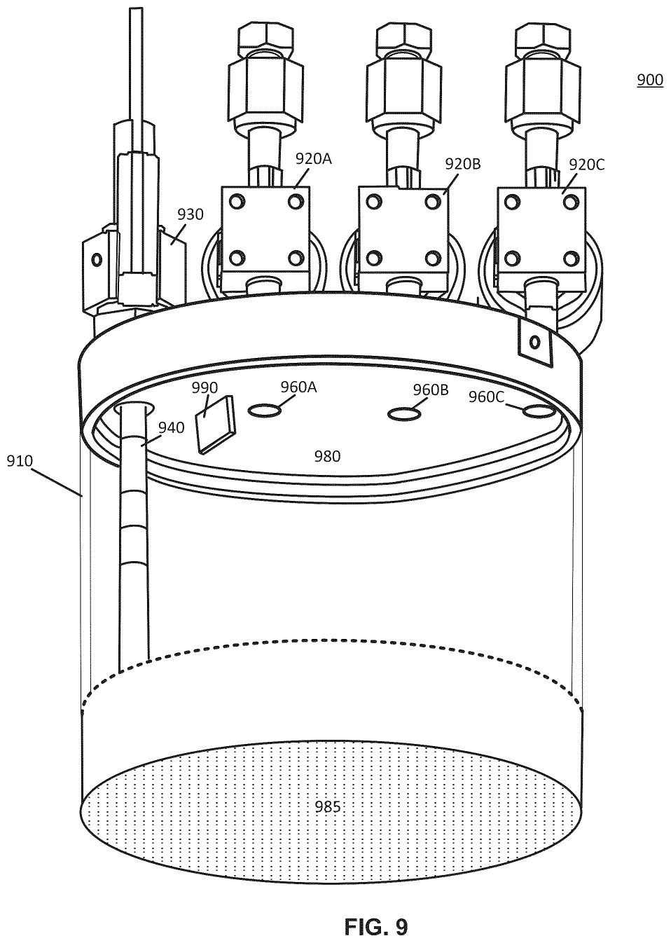

FIG. 9 illustrates a chemical vessel 900 in accordance with at least one embodiment of the invention. The chemical vessel 900 can be used as precursor vessel 610 within reaction system 600. The chemical vessel 900 comprises a vessel housing 910, a first valve 920A, a second valve 920B, a third valve 920C, and a liquid level sensor port 930.

The first valve 920A may be connected to a vacuum source or a liquid source (not illustrated). The second valve 920B may be connected to a reaction chamber (not illustrated), where deposition of a film may take place. The third valve 920C may be connected to a gas source (not illustrated). The valves 920A-920C may comprise a manual or pneumatic valve. The liquid level sensor port 930 may allow for electrical connections to a controller, to a processor, to a thermocouple, or to a heating element (not illustrated). These electrical connections may be located elsewhere on the chemical vessel 900.

The chemical vessel 900 may include additional parts similar to those illustrated in FIGS. 2-5B. The chemical vessel 900 may also include a liquid level sensor tube 940 (such as level sensor tubes 140 and other embodiments of level sensor tubes described herein), and a plurality of sensors (such as sensors 150A-150D). The liquid level sensor tube 940 may be connected to the liquid level sensor port 930. The vessel housing 910 comprises a top of the vessel housing 880, wherein the top of the vessel housing comprises valve inlet ports 860A-860C, which are in fluid communication with valves 820A-820C. The vessel housing 810 also comprises a bottom of the vessel housing 885.

A splash wall 990 is coupled to, and extends vertically from, the top of the vessel housing 980. A top surface of the splash wall (not illustrated) is (e.g., fixedly) coupled to the top of the vessel housing 980. The splash wall 990 is configured to be between the liquid level sensor tube 940 and the valve inlet port 960A. Therefore, the splash wall 990 is configured to prevent introduction of precursor to the chemical vessel 900 from contacting a top of the liquid level sensor 940. In certain embodiments, the top surface of the splash wall can be welded to the top of the vessel housing 980. The splash wall 990 comprises a splash wall bottom surface (not illustrated), which can extend from the top of the vessel housing 880 to the bottom of the vessel housing 885, or between about 10 millimeters and about 20 millimeters from the top of the vessel housing 880, or between about 10 millimeters and about 15 millimeters from the top of the vessel housing 880.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A chemical vessel comprising:
a vessel housing comprising a liquid level sensor port;
a liquid level sensor tube extending vertically from a top of the vessel housing a fixed depth into the vessel housing, the liquid level sensor tube comprising:
a liquid level sensor tube housing comprising an outer surface in direct contact with a liquid chemical precursor disposed in the vessel housing and having a sealed environment inside the vessel housing that is protected from the chemical precursor, the liquid level sensor tube housing comprising a slot that extends substantially an entire length of the liquid level sensor tube housing and that is configured to accommodate placement of the liquid chemical precursor therein;
a plurality of sensors disposed within the liquid level sensor tube housing in the sealed environment and located at particular vertical locations along the liquid level sensor tube associated with particular levels of the liquid chemical precursor in the vessel housing, wherein at least one of the plurality of sensors is in contact with an inside wall surface of the liquid level sensor tube housing; and
a shield coupled to the top of the vessel housing and surrounding at least a portion of the liquid level sensor tube housing, the shield comprising a cover wall extending vertically from the top of the vessel housing.

2. The chemical vessel of claim 1, wherein the liquid level sensor tube housing comprises an outer housing portion connected with an inner housing portion, and wherein the at least one of the plurality of sensors is in contact with an inside wall surface of the inner housing portion of the liquid level sensor tube housing.

3. The chemical vessel of claim 1, wherein the shield extends vertically from the top of the vessel housing to between about 2 millimeters and about 1 millimeter from of a bottom of the vessel housing.

4. The chemical vessel of claim 1, wherein the shield extends vertically from the top of the vessel housing to a bottom of the vessel housing.

5. The chemical vessel of claim 1, wherein the cover wall is disposed in front of the slot.

6. The chemical vessel of claim 1, wherein the shield comprises an opening extending from a top portion of the shield to a bottom portion of the shield.

7. The chemical vessel of claim 1, wherein the cover wall comprises a top portion that circumferentially surrounds the liquid level sensor tube and a bottom portion that partially surrounds the liquid level sensor tube.

8. The chemical vessel of claim 1, wherein the shield is welded to the top of the vessel housing.

9. A reaction system comprising:
a vessel comprising:
a vessel housing comprising a liquid level sensor port;
a liquid level sensor tube extending vertically from a top of the vessel housing a fixed depth into the vessel housing, the liquid level sensor tube comprising:
a liquid level sensor tube housing comprising an outer surface in direct contact with a liquid disposed in the vessel housing and having a sealed environment inside the vessel housing that is protected from the liquid, the liquid level sensor tube housing comprising a slot that extends a length along the liquid level sensor tube housing and that is configured to accommodate placement of the liquid therein;
a plurality of sensors disposed within the liquid level sensor tube housing in the sealed environment and located at particular vertical locations along the liquid level sensor tube associated with particular levels of the liquid in the vessel housing, wherein at least one of the plurality of sensors is in contact with an inside wall surface of the liquid level sensor tube housing; and
a shield coupled to the top of the vessel housing and surrounding at least a portion of the liquid level sensor tube housing, the shield comprising a cover wall extending vertically from the top of the vessel housing;
a reaction chamber, the reaction chamber being configured to hold a substrate and configured to receive a gas from the vessel; and
a liquid refill source configured to provide additional liquid to the vessel.

10. The reaction system of claim 9, wherein the shield extends vertically from the top of the vessel housing to between about 2 millimeters and about 1 millimeter from of a bottom of the vessel housing.

11. The reaction system of claim 9, wherein the shield extends vertically from the top of the vessel housing to a bottom of the vessel housing.

12. The reaction system of claim 9, wherein the cover wall is disposed in front of the slot.

13. The reaction system of claim 9, wherein the shield comprises an opening extending from a top portion of the shield to a bottom portion of the shield.

14. The reaction system of claim 9, wherein the cover wall comprises a top portion that circumferentially surrounds the liquid level sensor tube and a bottom portion that partially surrounds the liquid level sensor tube.

15. The reaction system of claim 9, wherein the shield is welded to the top of the vessel housing.

16. A chemical vessel comprising:
a vessel housing comprising a liquid level sensor port and an inlet port; and
a liquid level sensor tube extending vertically from a top of the vessel housing a fixed depth into the vessel housing, the liquid level sensor tube comprising:
a liquid level sensor tube housing comprising an outer surface in direct contact with a liquid disposed in the vessel housing and having a sealed environment inside the vessel housing that is protected from the liquid, the liquid level sensor tube housing comprising a slot that extends substantially an entire length of the liquid level sensor tube housing and that is configured to accommodate placement of the liquid therein;
a plurality of sensors disposed within the liquid level sensor tube housing in the sealed environment and located at particular vertical locations along the liquid level sensor tube associated with particular levels of the liquid in the vessel housing, wherein at least one of the plurality of sensors is in contact with an inside wall surface of the liquid level sensor tube housing; and
a splash wall extending vertically from the top of the vessel housing between the liquid level sensor tube and the inlet port.

17. The chemical vessel of claim 16, wherein the splash wall vertically extends from the top of the vessel housing between about 10 millimeters and about 20 millimeters.

18. The chemical vessel of claim 16, wherein the splash wall is fixedly coupled to the top of the vessel housing.

19. The chemical vessel of claim 16, wherein the splash wall is welded to the top of the vessel housing.

20. The chemical vessel of claim 16, wherein the splash wall is circular and surrounds the inlet port.
